(19) United States
(12) Patent Application Publication
(10) Pub. No.: US 2005/0139321 A1
(43) Pub. Date: Jun. 30, 2005

(54) Plasma processing apparatus

(75) Inventor: Tsutomu Higashiura, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Minato-ku (JP)

(21) Appl. No.: 11/024,656

(22) Filed: Dec. 30, 2004

Related U.S. Application Data
(63) Continuation of application No. PCT/JP03/08494, filed on Jul. 3, 2003.

(30) Foreign Application Priority Data
Jul. 3, 2002 (JP) 2002-194431

(51) Int. Cl. C23F 1/00; H01L 21/306

(52) U.S. Cl. 156/345.44; 156/345.29

(57) ABSTRACT

A plasma processing apparatus includes a chamber 11 for confining a plasma therein; an electrode 14 to which a power for use in generating the plasma is applied; a power supply 23 for supplying the power; an inner conductor 21 for supplying the power from the power supply 23 to the electrode 14; and an outer conductor 17 surrounding the inner conductor. Each of the chamber 11, the inner conductor 21 and the outer conductor 17 has a shape symmetrical with respect to a central axis which passes through a center of the electrode 14 and is perpendicular to the electrode 14. Further, structures 28, 29, 30 and 31 are symmetrically provided with respect to the central axis in the outer conductor 17, and at least one of the structures is a dummy structure 29 having a same shape as that of one of the other structures.

This application is a Continuation Application of PCT International Application No. PCT/JP03/08494 filed on Jul. 3, 2003, which designated the United States.

### FIELD OF THE INVENTION

The present invention relates to a plasma processing apparatus.

### BACKGROUND OF THE INVENTION

A plasma processing apparatus is employed to perform a predetermined processing on a semiconductor substrate, a liquid crystal substrate or the like, by using a plasma. A plasma etching apparatus for performing an etching processing on a substrate and a plasma CVD (chemical vapor deposition) apparatus for performing a CVD processing on a substrate are examples of such plasma processing apparatuses. Among various plasma processing apparatuses, a parallel plate type apparatus is widely employed due to its advantages that it has a relatively simple structure and is capable of executing a uniform processing.

The parallel plate type plasma processing apparatus includes a vacuum vessel (chamber) in which two flat plate electrodes are respectively disposed at an upper portion and a lower portion thereof to face each other in parallel. One of the two flat plate electrodes (lower electrode) has a mounting table to mount thereon an object to be processed. The other flat plate electrode (upper electrode) has an electrode plate provided with a plurality of gas holes on its surface facing the lower electrode. The upper electrode is connected to a processing gas supply source. A processing gas from the processing gas supply source is supplied into a space (plasma generation space) between the upper electrode and the lower electrode via the gas holes of the electrode plate.

A plasma of the supplied processing gas is generated by applying a high frequency power to the upper electrode. The generated plasma is pulled into the vicinity of the lower electrode which receives an AC power having a frequency lower than that of the high frequency power applied to the upper electrode. A predetermined processing is performed on the object to be processed mounted on the lower electrode by the thus pulled plasma.

Further, an electrode housing for supporting the upper electrode is disposed on the vacuum vessel. The electrode housing also serves as an outer conductor through which the high frequency power flows when it returns to the ground. Moreover, an impedance matching device is installed on the electrode housing. Each of the electrode housing and the matching device has an individual housing formed of a metallic material. Openings are formed in contact walls of those metallic housings, and a power feed rod is installed through the openings. A high frequency power from a high frequency oscillator is supplied to the upper electrode via the power feed rod.

Further, incorporated in the electrode housing are a gas supply line for supplying a processing gas, and a coolant supply line and a coolant discharge line for circulating a coolant through the upper electrode thereof.

Moreover, the electrode housing also includes therein high frequency circuits such as a low frequency filter for extracting a DC component from a high frequency power and a trap circuit for performing a virtual ground of a frequency of a power applied to a facing electrode (for example, lower electrode).

However, the plasma processing apparatus incorporating the plurality of structures in the electrode housing suffers from various problems as follows.

First, a structure installed inside the electrode housing disturbs a high frequency electromagnetic field inside the outer conductor and, as a consequence, the symmetry of generated plasma is broken. That is, the distribution of the plasma generated in the vacuum vessel becomes nonuniform, which in turn causes a variation (nonuniformity) in quality among devices formed on a single object to be processed (wafer).

Further, since the electrode housing and the matching device has their respective housings, a return path of the high frequency power is lengthened, which results in an increase of impedance and loss of a high frequency power supplied to generate a plasma. That is to say, the amount of high frequency power supplied to the upper electrode is reduced.

Furthermore, when a plurality of structures is installed in the electrode housing, it becomes difficult to secure an installation place for a high frequency circuit. Particularly, the volume and the dimension of an air core coil constituting the high frequency circuit are large and requires a certain space for the installation thereof. Moreover, the presence of the high frequency circuit may hinder the installation of additional structures.

In addition, when an impedance matching is not achieved, a reflection wave is generated due to the supply of the high frequency power. Once generated, the reflection wave returns to the high frequency oscillator to cause an increase of voltage and/or loss of high frequency power, while imposing adverse effects on the high frequency oscillator.

In case the strength of the reflection wave exceeds a predetermined level, the high frequency oscillator can be protected by dropping the output level of the high frequency power abruptly or by temporarily stopping outputting the high frequency power. In such a case, however, there is a likelihood that the generation of plasma becomes unstable or a plasma may even extinguish, thereby causing adverse effects on the quality of the wafer.

### SUMMARY OF THE INVENTION

It is, therefore, a first object of the present invention to provide a plasma processing apparatus capable of stably obtaining a high-quality wafer.

It is a second object of the present invention to provide a plasma processing apparatus capable of distributing a generated plasma uniformly.

It is a third object of the present invention to provide a plasma processing apparatus having a short return path of a current.

It is a fourth object of the present invention to provide a plasma processing apparatus capable of easily securing an installation place for an in-housing structure for supporting an electrode for plasma generation.

It is a fifth object of the present invention to provide a plasma processing apparatus capable of stably generating a plasma.

In order to achieve the objects described above, a plasma processing apparatus in accordance with a preferred embodiment of the present invention includes a plasma processing apparatus having a chamber 11 for confining a plasma therein; an electrode 14, installed in the chamber 11, to which a power for use in generating the plasma is applied; a power supply 23 for supplying the power; an inner conductor 21 for supplying the power from the power supply 23 to the electrode 14; and an outer conductor 17 surrounding the inner conductor, wherein each of the chamber 11, the inner conductor 21 and the outer conductor 17 has a shape symmetrical with respect to a central axis which passes through a center of the electrode 14 and is perpendicular to the electrode 14, a plurality of structures 28, 29, 30 and 31 are symmetrically provided with respect to the central axis in the outer conductor 17, and at least one of the plurality of structures is a dummy structure 29 having a same shape as that of one of the other structures.

In accordance with another preferred embodiment of the present invention, there is provided a plasma processing apparatus having a chamber 11 for generating a plasma therein; an electrode 14 for receiving a power for use in generating the plasma; a power supply 23 for supplying the power to the electrode 14; a processing circuit 50 for performing a predetermined processing on the power supplied to the electrode 14; and a tube 28 for feeding a gas therethrough, the plasma processing apparatus including: an enclosure 17, installed on the chamber 11, for supporting the electrode 14, wherein the tube 28 is formed in a coil shape and one end thereof is electrically connected to the electrode 14, while forming a part of the processing circuit 50, and the processing circuit is installed inside the enclosure 17.

In accordance with still another preferred embodiment of the present invention, there is provided a plasma processing apparatus including a chamber 11 for generating a plasma therein; an electrode 14 for receiving a power for use in generating the plasma; a power supply 23 for supplying the power to the electrode 14; a processing circuit 50 for performing a predetermined processing on the power supplied to the electrode 14; and a tube 28 for feeding a gas therethrough, wherein the processing circuit 50 is a trap circuit, and the tube 28 is formed in a coil shape and one end thereof is electrically connected to the electrode 14, the tube 28 being used as a coil element which constitutes the trap circuit.

### BRIEF DESCRIPTION OF THE DRAWINGS

The above and other objects and features of the present invention will become apparent from the following description of preferred embodiments, given in conjunction with the accompanying drawings, in which:

FIG. 1 is a partial cross sectional view showing a configuration of a plasma CVD apparatus in accordance with a first preferred embodiment of the present invention;

FIG. 2 provides a cross sectional view illustrating the interior of an electrode housing or the like shown in FIG. 1;

FIG. 3 sets forth a plan view of the interior of the electrode housing;

FIG. 4 presents a cross sectional view illustrating the interior of an electrode housing or the like of a plasma CVD apparatus in accordance with a second preferred embodiment of the present invention;

FIG. 5 is an enlarged cross sectional view of FIG. 4;

FIG. 6 depicts a cross sectional view showing the interior of an electrode housing or the like of a conventional plasma CVD apparatus;

FIG. 7 offers an enlarged cross sectional view of FIG. 6;

FIG. 8 is a cross sectional view illustrating the interior of an electrode housing of a plasma CVD apparatus in accordance with a third preferred embodiment of the present invention;

FIG. 9A shows a detailed configuration of a high frequency circuit installed inside the electrode housing shown in FIG. 8, while FIG. 9B illustrates an equivalent circuit of the high frequency circuit shown in FIG. 9A;

FIG. 10 describes a configuration of a plasma CVD apparatus in accordance with a fourth preferred embodiment of the present invention;

FIG. 11 explains a configuration of a conventional plasma CVD apparatus.

### DETAILED DESCRIPTION OF THE PREFERRED EMBODIMENTS

Preferred embodiments of the present invention will now be described with reference to the accompanying drawings. In the following, description will be made with regard to a plasma CVD (chemical vapor deposition) apparatus as an example of a plasma processing apparatus.

### First Preferred Embodiment

A plasma CVD apparatus in accordance with a first embodiment has a configuration in which a high frequency electromagnetic field formed inside an electrode housing is not disturbed by a structure installed inside the electrode housing, which serves to support an upper electrode.

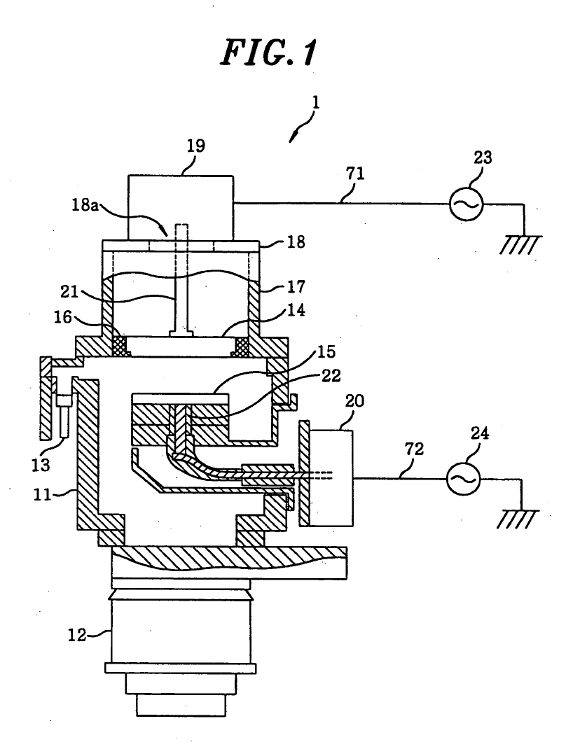

Referring to FIG. 1, there is illustrated a configuration of a plasma CVD apparatus 1 in accordance with the first preferred embodiment.

The plasma CVD apparatus 1 is a so-called parallel plate type plasma processing apparatus including an upper and a lower electrode placed to face each other in parallel, and forms, e.g., a SiOF film on a surface of a semiconductor wafer (hereinafter referred to as a wafer) employed as an object to be processed.

The plasma CVD apparatus 1 includes a vacuum vessel (chamber) 11 and a pump 12.

A turbo molecular pump is employed as the pump 12, for example. The pump 12 exhausts a gas from the vacuum vessel 11 to thereby produce a depressurized atmosphere therein. Specifically, the pump 12 sets an internal pressure of the vacuum vessel 11 to be a predetermined level, e.g., less than 0.01 Pa.

A shutter 13 is installed at the side of the vacuum vessel 11.

In the vacuum vessel 11, an upper electrode 14 and a lower electrode 15 are disposed.

The lower electrode 15 is formed of a conductor with a high melting point, e.g., molybdenum. The wafer is mounted on the lower electrode 15 via an insulating member (not shown), or the like. A heater (not shown) formed of, for example, a nichrome wire is disposed below the lower electrode 15. Further, a coolant passageway (not shown) through which a coolant circulates to control the temperature of the lower electrode 15 is formed within the lower electrode 15.

The upper electrode 14 is placed to face the lower electrode 15 in parallel and is supported by a cylindrical enclosure 17 via an insulating member 16. A ceiling plate 18 is placed on the enclosure 17. Further, the enclosure 17 also serves as an outer conductor through which a high frequency power applied to the upper electrode 14 returns to the ground.

The plasma CVD apparatus 1 employs a dual frequency excitation method. That is to say, the plasma CVD apparatus 1 includes a high frequency oscillator 23 for supplying a high frequency power to the upper electrode 14 and a high frequency oscillator 24 for supplying a high frequency power to the lower electrode 15.

The high frequency oscillator 23 outputs a high frequency power of a frequency ranging from 13 to 150 MHz. The high frequency power from the high frequency oscillator 23 generates a high frequency electric field between the upper and the lower electrode 14 and 15, and is used to generate a plasma of a processing gas.

The high frequency oscillator 24 outputs a high frequency power of a frequency ranging from 0.1 to 13 MHz. The high frequency power from the high frequency oscillator 24 is used to pull ions among the plasma to the vicinity of the lower electrode 15 and to control ion energy around the wafer surface.

Further, the high frequency oscillator 23 and 24 are both connected to the ground of the plasma CVD apparatus 1. Here, the ground of the plasma CVD apparatus 1 can be connected to an earth ground.

Matching devices 19 and 20 are installed on the ceiling plate 18 and at the side of the vacuum vessel 11, respectively. The matching devices 19 and 20 carries out an impedance matching between the upper electrode 14 and a transmission line 71 and between the lower electrode 15 and a transmission line 72, respectively, to thereby prevent a generation of standing wave caused by a reflection wave.

The ceiling plate 18 has an opening 18a and a power feed rod 21 is installed therethrough. Further, a power feed rod 22 is interposed between the lower electrode 15 and the matching device 20. The power feed rods 21 and 22 serve as inner conductors for supplying high frequency powers to the upper electrode 14 and the lower electrode 15, respectively.

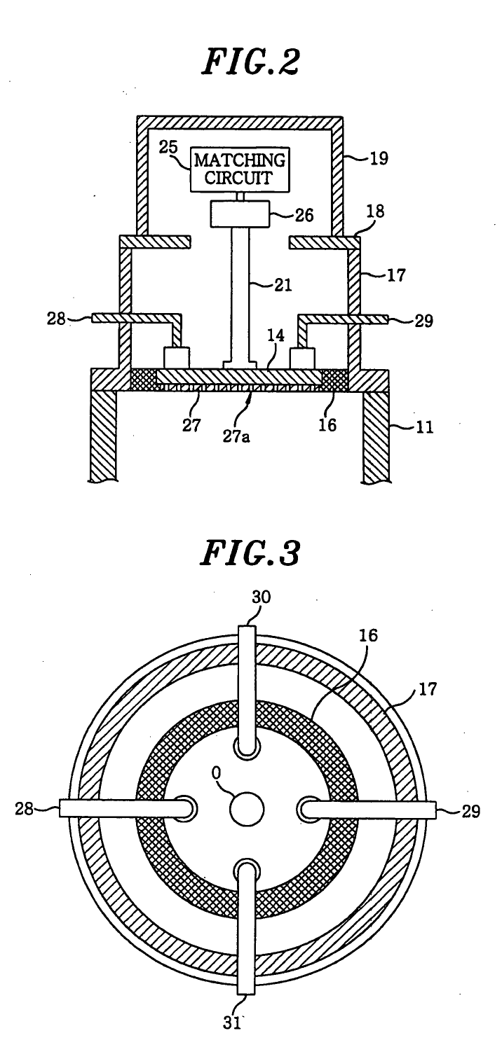

The matching device 19 incorporates therein a matching circuit 25, as shown in FIG. 2, and the matching device 20 also includes therein a similar matching circuit. Further installed in the matching device 19 is a connecting member 26 which serves to connect the power feed rod 21 to the matching circuit 25 electrically. One end of the power feed rod 21 is coupled to the matching circuit 25 via the connecting member 26 while the other end thereof is connected to the upper electrode 14. By this configuration, the high frequency power from the high frequency oscillator 23 is supplied to the upper electrode 14 via the matching circuit 25 and the power feed rod 21. Moreover, the housing of the matching device 19 also serves as an outer conductor through which the high frequency power applied to the upper electrode 14 returns to the ground.

Formed inside the upper electrode 14 are a coolant passageway (not shown) through which a coolant circulates to control the temperature of the upper electrode 14 and a hollow portion (not shown) for diffusing a processing gas. Further, an electrode plate 27 made of aluminum or the like is installed on a facing surface of the upper electrode 14's toward the lower electrode 15. The electrode plate 27 is provided with a plurality of gas holes 27a in communication with the hollow portion of the upper electrode 14.

Installed inside the enclosure 17 are a gas supply tube 28 and a dummy tube 29. The gas supply tube 28 is installed to supply the processing gas from an external processing gas supply source (not shown) into the hollow portion of the upper electrode 14.

The processing gas supplied into the hollow portion of the upper electrode 14 from the processing gas supply source via the gas supply tube 28 is diffused inside the hollow portion and is discharged toward the wafer through the gas holes 27a. Various types of gases can be employed as the processing gas. For example, in case of forming a SiOF film, a SiF₄ gas, a SiH₄ gas, an O₂ gas, an NF₃ gas, an NH₃ gas, and an Ar gas as a dilution gas may be employed as the processing gas as in conventional cases.

The dummy tube 29 is installed to distribute the plasma uniformly and has a shape identical to that of the gas supply tube 28 and is made of the same material as used to form the gas supply tube 28. However, the processing gas or the like does not pass through the dummy tube 29.

FIG. 3 shows a state of an interior of the enclosure 17 observed with the naked eye from the top after removing the matching device 19, the matching circuit 25 and the connecting member 26. As shown in FIG. 3, a coolant supply tube 30 and a coolant discharge tube 31 are installed in the enclosure 17 in addition to the gas supply tube 28 and the dummy tube 29.

The coolant supply tube 30 is for supplying the coolant for controlling the temperature of the upper electrode 14 into the upper electrode 14, and the coolant discharge tube 31 is for discharging the coolant from the upper electrode 14. The coolant supply tube 30 and the coolant discharge tube 31 have a same shape and are made of a same material.

As shown in FIG. 3, the gas supply tube 28, the dummy tube 29, the coolant supply tube 30 and the coolant discharge tube 31 are symmetrically disposed with respect to the center point O. The center point O lies on a central axis of symmetry which passes through the center of the upper electrode 14 and to be normal thereto. The central axis of symmetry passes through the centers of the vacuum vessel 11, the upper electrode 14 and the lower electrode 15.

Moreover, the structures (the gas supply tube 28, the dummy tube 29, the coolant supply tube 30 and the coolant discharge tube 31) in the enclosure 17 are surface-treated in an identical manner and are installed by a same fixing method.

Further, the high frequency circuit and so forth in the enclosure 17 are also symmetrically disposed with respect to the center point O (central axis of symmetry). Moreover, each of the vacuum vessel 11, the enclosure 17, the ceiling plate 18, the matching device 19 and the power feed rod 21 is formed in a shape, e.g., cylindrical shape, having symmetry with respect to the center point O (central axis of symmetry).

As described above, the vacuum vessel 11, the enclosure 17, the ceiling plate 18, the matching device 19 and all the structures embedded in the enclosure 17 are symmetrically disposed with respect to the center point O (central axis of symmetry).

Next, operation of the plasma CVD apparatus 1 in accordance with the first preferred embodiment of the present invention will be described.

When a wafer is loaded on the lower electrode 15, the wafer is electrostatically attracted and held by a high temperature electrostatic chuck (not shown). Then, the shutter 13 is closed and the gas in the vacuum vessel 11 is exhausted by the pump 12. As a result, the inside of the vacuum vessel 11 is set to be at a predetermined high vacuum level (for example, 0.01 Pa).

In this state, a coolant circulates through the coolant passageway formed inside the lower electrode 15, so that the temperature of the lower electrode 15 is controlled to be, for example, 50° C.

Thereafter, a process gas and a dilution gas (carrier gas) are supplied to the upper electrode 14 from the processing gas supply source via the gas supply tube 28 at preset flow rates. The process gas includes, for example, a SiF₄ gas, a SiH₄ gas, an O₂ gas, an NF₃ gas and an NH₃ gas, while the dilution gas is, for example, an Ar gas.

The supplied processing gas is introduced into the vacuum vessel 11 via the hollow portion of the upper electrode 14 and the gas holes 27a of the electrode plate 27. At this time, the process gas and the carrier gas are uniformly discharged toward the wafer from the gas holes 27a of the electrode plate 27.

Thereafter, the high frequency oscillator 23 applies a high frequency power to the upper electrode 14 via the matching device 19 and the power feed rod 21, whereby a high frequency electric field is formed between the upper electrode 14 and the lower electrode 15 to generate a plasma of the supplied processing gas.

Meanwhile, the high frequency oscillator 24 applies a high frequency power to the lower electrode 15 via the matching device 20 and the power feed rod 22, whereby ions among the plasma are pulled to the vicinity of the lower electrode 15, and the ion energy around the wafer surface is controlled.

By the application of the high frequency powers to the upper and the lower electrode 14 and 15, the plasma of the processing gas is generated and a SiOF film is formed on the surface of the wafer by a chemical reaction thereon-caused by the plasma.

A current generated by the high frequency power from the high frequency oscillator 23 flows through the inner walls of the enclosure 17 and the matching device 19 to be directed to the ground of the high frequency oscillator 23. At this time, when the return path of the current is asymmetrical with respect to the central axis of symmetry, the plasma generated in the vacuum vessel 11 may be distributed in a nonuniform fashion, that is, the plasma distribution would be off-center.

However, the vacuum vessel 11, the enclosure 17, the ceiling plate 18, the matching device 19 and all the structures accommodated in the enclosure 17 are installed to be symmetrical with respect to the center point O (central axis of symmetry) as described above. Hence, the generated plasma is prevented from being off-center, and gets uniformly distributed in the vacuum vessel 11 with respect to the central axis of symmetry.

As described above, in accordance with the first preferred embodiment, the dummy tube 29 having the same shape as that of the gas supply tube 28 and made of the same material as that used to form the gas supply tube 28 is installed in the enclosure 17 and all the structures in the enclosure 17 are symmetrically disposed with respect to the center point O. As a result, the plasma generated in the vacuum vessel 11 can be uniformly distributed, thereby enabling the uniform quality to be established in a number of chips formed on the wafer.

Furthermore, though the first preferred embodiment has been described for the case of having only one dummy tube 29, it is possible to vary the number of dummy tubes depending on the number of the structures installed in the enclosure 17.

Moreover, it is also possible to dispense with dummy tube 29. In such a case, the gas supply tube 28, the coolant supply tube 30 and the coolant discharge tube 31 may be formed by using tubes having a same shape and made of a same material and may be disposed in three different directions such that they are symmetrical with respect to the center point O.

### Second Preferred Embodiment

A plasma CVD apparatus 1 in accordance with a second preferred embodiment is configured to have a shorter return path of a high frequency power applied to an upper electrode 14 in order to suppress a power loss.

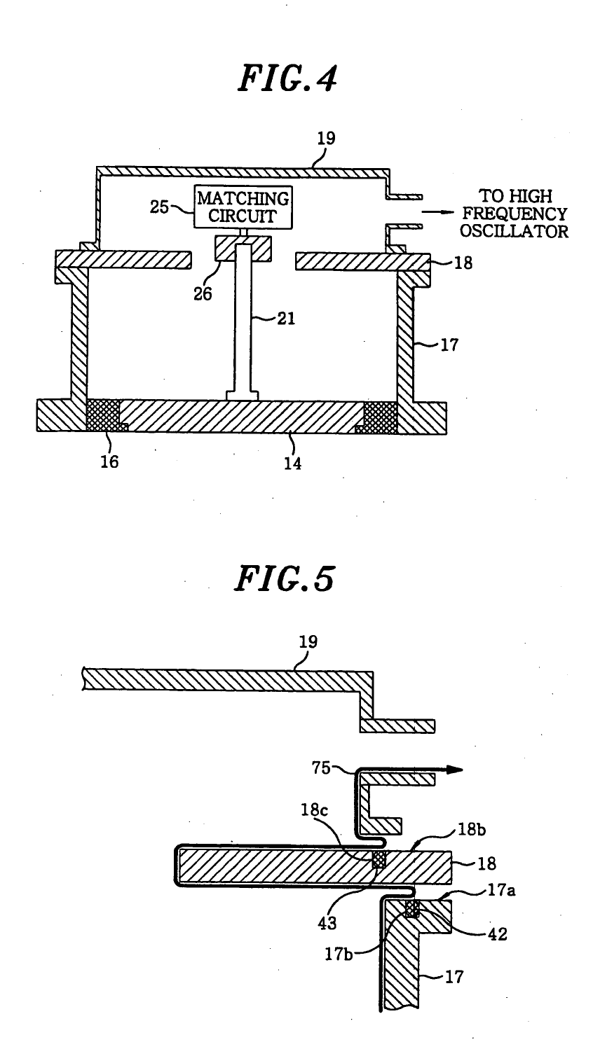

FIG. 4 shows the configuration of the plasma CVD apparatus 1 in accordance with the second preferred embodiment.

In the plasma CVD apparatus 1 in accordance with the second preferred embodiment, a matching device 19 does not have a conventionally employed bottom plate and a ceiling plate 18 of an enclosure 17 also serves as the bottom plate of the matching device 19 instead.

As shown in FIG. 5, a groove 17b is formed on an enclosure 17's end surface 17a to be attached to the ceiling plate 18. An elastic gasket 42 for preventing a leakage of the high frequency is disposed in the groove 17b. Once the enclosure 17 and the ceiling plate 18 are tightly fastened by screws or the like, the gasket 42 is deformed to thereby seal the gap between the enclosure 17 and the ceiling plate 18.

Furthermore, a groove 18c is also formed in a ceiling plate 18's end surface 18b to be attached to the matching device 19, and an elastic gasket 43 for preventing a leakage of the high frequency is disposed in the groove 18c. When the ceiling plate 18 and the matching device 19 are tightly jointed by screws or the like, the gasket 43 is deformed to thereby seal the gap between the ceiling plate 18 and the matching device 19.

By the above configurations, the insides of the enclosure 17 and the matching device 19 are hermetically sealed. The high frequency power applied to the upper electrode 14 is returned to the high frequency oscillator 23 via the inner walls of the enclosure 17, the ceiling plate 18 and the matching device 19, as shown by an arrow 75 in FIG. 5.

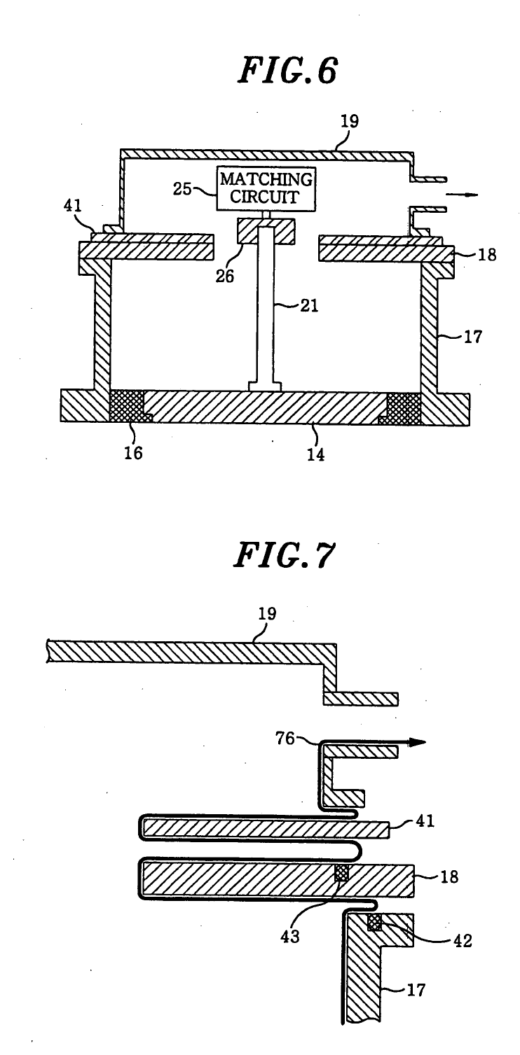

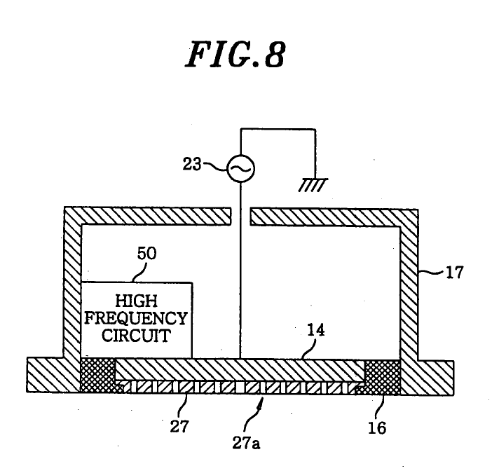

In conventional plasma CVD apparatus, a separate bottom plate 41 of a matching device 19 is prepared independently of a ceiling plate 18 of an enclosure 17, as shown in FIG. 6. Therefore, in the conventional plasma CVD apparatus, the high frequency power applied to an upper electrode 14 is returned to the high frequency oscillator 23 via the bottom plate 41 of the matching device 19 after passing through the enclosure 17 and the ceiling plate 18, as shown by an arrow 76 in FIG. 7. As described, the return path of the high frequency power is longer in the conventional plasma CVD apparatus.

However, in the plasma CVD apparatus in accordance with the second preferred embodiment, the matching device 19 is devoid of a bottom plate and the ceiling plate 18 doubles as the bottom plate of the matching device 19 instead. As a result, the return path of the high frequency power becomes shorter than that in the conventional case. If the return path of the high frequency power becomes shorter, impedance is also reduced, so that the loss of the high frequency power can be suppressed. As a result, the operation of the plasma CVD apparatus 1 can be stabilized.

### Third Preferred Embodiment

In a plasma CVD apparatus 1 in accordance with a third preferred embodiment, a gas supply tube 28, which is one of various structures installed in an enclosure 17, is utilized as a coil element in order to secure installation places for other structures therein.

As shown in FIG. 8, a high frequency circuit 50 is installed inside the enclosure 17. As will be described hereinbelow, the gas supply tube 28 serving as the coil element constitutes the high frequency circuit 50.

In the third preferred embodiment, a high frequency voltage supplied from the high frequency oscillator 23 is supplied to the upper electrode 14 with a DC voltage superposed thereon.

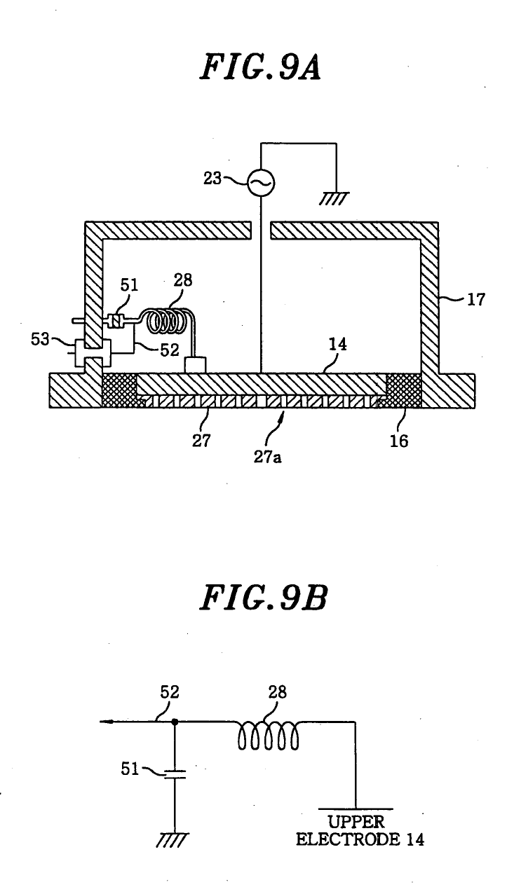

As shown in FIG. 9A, one end of the gas supply tube 28 is connected to the upper electrode 14 while the other end thereof is coupled to the enclosure 17 via a dielectric 51. The gas supply tube 28 is formed of a metal (conductor) and is wound in a coil shape. The dielectric 51 isolates the gas supply tube 28 from the ground potential. The gas supply tube 28 and the dielectric 51 constitute a low pass filter which serves as the high frequency circuit 50.

Moreover, the dielectric 51 is formed in, for example, a ring shape in order to allow a gas to flow therethrough. Besides, the coolant supply tube 30 or the coolant discharge tube 31 can be used as the coil element instead of the gas supply tube 28 by being wound in a coil shape.

In addition, a covered wire 52 covered with an insulating material is connected to the other end of the gas supply tube 28. The covered wire 52 is extended to the outside of the enclosure 17 to be connected to an external DC detecting circuit. Polytetrafluoroethylene or the like may be used as a coating material of the covered wire 52. An insulating member 53 is interposed between the covered wire 52 and the enclosure 17. By the insulating member 53, the covered wire 52 is supported and the inside of the enclosure 17 is hermetically sealed. An equivalent circuit diagram is shown in FIG. 9B.

The gas supply tube 28 and the dielectric 51 function as a coil and a capacitor, respectively, and constitute the low pass filter. The low pass filter is formed on the upper electrode 14. When a high frequency power is supplied to the upper electrode 14 from the high frequency oscillator 23, a DC component of the high frequency power passes through the low pass filter and is outputted to the DC detecting circuit via the covered wire 52.

As described above, by designing the gas supply tube 28 to further serve as a coil element having great volume and dimension, the interior space of the enclosure 17 can be saved, whereby installation places for the high frequency circuit 50 and the above-described multiple structures can be secured inside the enclosure 17.

Moreover, the gas supply tube 28 can also be used in various types of high frequency circuits (for example, a trap circuit) for performing a certain processing on the high frequency power supplied to the upper electrode 14.

### Fourth Preferred Embodiment

A plasma CVD apparatus 1 in accordance with a fourth preferred embodiment has a circulator interposed between the high frequency oscillator 23 and the matching device 19 in order to prevent an unstable operation of the high frequency oscillator 23 due to a reflection wave generated by a supply of a high frequency power.

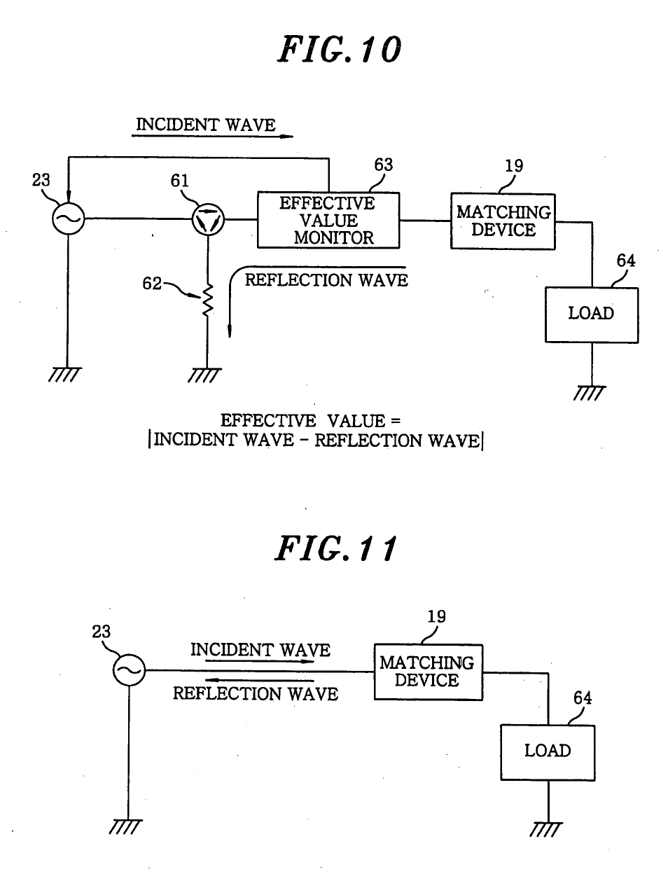

FIG. 10 shows the configuration of the plasma CVD apparatus 1 in accordance with the fourth preferred embodiment.

The plasma CVD apparatus 1 in accordance with the fourth embodiment includes a circulator 61 interposed between the high frequency oscillator 23 and the matching device 19.

The circulator 61 has three input/output ports, one of which is grounded via a dummy load 62. One of the other two is connected to the high frequency oscillator 23, while the last one is coupled to the matching device 19 via an effective value monitor 63.

The circulator 61 has a characteristic that it outputs an input from an arbitrary input/output port to a specific port for that arbitrary port, and a ferrite device and the like is embedded in the circulator 61. Specifically, the circulator 61 attains such a characteristic by a magnetic field applied to the ferrite device.

With this characteristic, the circulator 61 transmits an incident wave supplied from the high frequency oscillator 23 to the matching device 19 via the effective value monitor 63, and sends a reflection wave outputted from the effective value monitor 63 to the ground via the dummy load 62. Further, the circulator 61 varies an amount of the reflection wave being transmitted to the ground according to the strength of the reflection wave.

Moreover, the effective value monitor 63 detects the difference between the incident wave and the reflection wave and transmits a monitoring signal representing the detection result to the high frequency oscillator 23. Based on the detection result represented by the monitoring signal received from the effective value monitor 63, the high frequency oscillator 23 controls a supply of the high frequency power such that the difference between the incident wave and the reflection wave is maintained constant.

Furthermore, the circulator of the type may be provided between the high frequency oscillator 24 and the matching device 20 as well.

Hereinbelow, an operation of the plasma CVD apparatus 1 in accordance with the forth preferred embodiment will be described.

An incident wave from the high frequency oscillator 23 is inputted to the circulator 61. Then, the circulator 61 outputs the incident wave to the matching device 19 via the effective value monitor 63. When an impedance matching is not achieved between a load 64 of the upper electrode 14 and a transmission line, a reflection wave is transmitted toward the high frequency oscillator 23 from the matching device 19.

As shown in FIG. 11, if the circulator 61 is not installed, the reflection wave from the matching device 19 is transmitted to the high frequency oscillator 23, considerably producing adverse effects thereon.

However, in case the circulator 61 is provided between the high frequency oscillator 23 and the matching device 19 as shown in FIG. 10, the reflection wave from the matching device 19 is inputted to the circulator 61 to be separated from the incident wave. The circulator 61 sends the reflection wave from the matching device 19 to the ground via the dummy load 62.

At this time, the effective value monitor 63 detects the difference between the incident wave and the reflection wave and outputs the monitoring signal representing the detection result to the high frequency oscillator 23. The high frequency oscillator 23 controls the supply of the high frequency power based on the detection result (the difference) represented by the monitoring signal from the effective value monitor 63 such that the difference between the incident wave and the reflection wave is maintained constant.

As described above, by installing the circulator 61 between the high frequency oscillator 23 and the matching device 19, the high frequency oscillator 23 can be simply protected from the reflection wave. Thus, the stable operation of the high frequency oscillator 23 can be guaranteed without having to abruptly drop the high frequency power provided from the high frequency oscillator 23 or to temporarily stop the supply of the high frequency power. As a result, plasma generation can be carried out in a stable manner, so that the quality of the wafer can be maintained high.

Further, by regulating the strength of the incident wave sended to the load 64 at a constant level, the effective value monitor 63 can be omitted.

The present invention is not limited to the above-described preferred embodiments but can be varied in various ways.

For example, the object to be processed is not limited to the semiconductor wafer but can be a liquid crystal display device, etc. Furthermore, a film formed on the object to be processed can be any kind, e.g., a SiO₂ film, a SiN film, a SiC film, a SiCOH film or a CF film.

Moreover, the present invention is not limited to the film forming process but can also be applied to, for example, an etching process. Further, in addition to the parallel plate type plasma processing apparatus, the present invention can be applied to any various plasma processing apparatus having an electrode in a chamber, such as a magnetron type plasma processing apparatus.

Further, it is preferable to configure a plasma processing apparatus by combining the first to the fourth embodiments appropriately.

Furthermore, the present invention is based upon Japanese Patent Application No. 2002-194431 filed on Jul. 3, 2002 and incorporates therein the specification, the claims, the drawings and the abstract thereof. The entire contents of the above-identified application are incorporated herein by reference.

While the invention has been shown and described with respect to the preferred embodiment, it will be understood by those skilled in the art that various changes and modifications may be made without departing from the spirit and scope of the invention as defined in the following claims.

1. A plasma processing apparatus having a chamber 11 for confining a plasma therein; an electrode 14, installed in the chamber 11, to which a power for use in generating the plasma is applied; a power supply 23 for supplying the power; an inner conductor 21 for supplying the power from the power supply 23 to the electrode 14; and an outer conductor 17 surrounding the inner conductor,
wherein each of the chamber 11, the inner conductor 21 and the outer conductor 17 has a shape symmetrical with respect to a central axis which passes through a center of the electrode 14 and is perpendicular to the electrode 14,
a plurality of structures 28, 29, 30 and 31 are symmetrically provided with respect to the central axis in the outer conductor 17, and
at least one of the plurality of structures is a dummy structure 29 having a same shape as that of one of the other structures.

2. The apparatus of claim 1, wherein the dummy structure 29 is formed of a same material that is employed to form said one of the other structures.

3. A plasma processing apparatus having a chamber 11 for generating a plasma therein; an electrode 14 for receiving a power for use in generating the plasma; a power supply 23 for supplying the power to the electrode 14; a processing circuit 50 for performing a predetermined processing on the power supplied to the electrode 14; and a tube 28 for feeding a gas therethrough, the plasma processing apparatus comprising:
an enclosure 17, installed on the chamber 11, for supporting the electrode 14,
wherein the tube 28 is formed in a coil shape and one end thereof is electrically connected to the electrode 14, while forming a part of the processing circuit 50, and the processing circuit is installed inside the enclosure 17.

4. The apparatus of claim 3, wherein the tube 28 is a gas supply tube for supplying a processing gas into the chamber 11 from the outside thereof.

5. The apparatus of claim 4, wherein the processing circuit 50 is a filter circuit and the tube 28 is used as a coil element which constitutes the filter circuit.

6. The apparatus of claim 3, further comprising:
a transmission line 71 for supplying the power from the power supply 23 to the electrode 14;
a matching device 19 for performing an impedance matching between the electrode 14 and the transmission line 71; and
a protector 61 for preventing a reflection wave generated by the supply of the power from being transmitted to the power supply 23.

7. The apparatus of claim 6, wherein the protector 61 is constituted by a circulator provided with a plurality of input/output ports, one of the input/output ports being grounded, and the circulator transmits the reflection wave to a ground.

8. The apparatus of claim 7, wherein the protector 61 controls an amount of the reflection wave being transmitted to the ground according to the strength of the reflection wave.

9. The apparatus of claim 3, further comprising:
a transmission line 71 for supplying the power from the power supply 23 to the electrode 14; and
a matching device 19, installed on the enclosure 17, for performing an impedance matching between the electrode 14 and the transmission line 71,
wherein the enclosure 17 has a ceiling plate 18 and the ceiling plate 18 serves as a bottom plate of the matching device 19.

10. A plasma processing apparatus comprising a chamber 11 for generating a plasma therein; an electrode 14 for receiving a power for use in generating the plasma; a power supply 23 for supplying the power to the electrode 14; a processing circuit 50 for performing a predetermined processing on the power supplied to the electrode 14; and a tube 28 for feeding a gas therethrough,
wherein the processing circuit 50 is a trap circuit and
the tube 28 is formed in a coil shape and one end thereof is electrically connected to the electrode 14, the tube 28 being used as a coil element which constitutes the trap circuit.

11. The apparatus of claim 10, further comprising an enclosure 17, installed on the chamber 11, for supporting the electrode 14, wherein the processing circuit 50 is installed inside the enclosure 17.

12. The apparatus of claim 11, wherein the tube 28 is a gas supply tube for supplying a processing gas into the chamber 11 from the outside thereof.

13. The apparatus of claim 10, further comprising:
a transmission line 71 for supplying the power from the power supply 23 to the electrode 14;
a matching device 19 for performing an impedance matching between the electrode 14 and the transmission line 71; and
a protector 61 for preventing a reflection wave generated by the supply of the power from being transmitted to the power supply 23.

14. The apparatus of claim 13, wherein the protector 61 is constituted by a circulator provided with a plurality of input/output ports, one of the input/output ports being grounded, and the circulator transmits the reflection wave to a ground.

15. The apparatus of claim 14, wherein the protector 61 controls an amount of the reflection wave being transmitted to the ground according to the strength of the reflection wave.

16. The apparatus of claim 10, wherein the tube 28 is a gas supply tube for supplying a processing gas into the chamber 11 from the outside thereof.

17. The apparatus of claim 10, further comprising:
a transmission line 71 for supplying the power from the power supply 23 to the electrode 14;
an enclosure 17, installed on the chamber 11, for supporting the electrode 14; and
a matching device 19, installed on the enclosure 17, for performing an impedance matching between the electrode 14 and the transmission line 71,
wherein the enclosure 17 has a ceiling plate 18 and the ceiling plate 18 serves as a bottom plate of the matching device 19.
